(19) United States
(12) Patent Application Publication
(10) Pub. No.: US 2025/0226838 A1
(43) Pub. Date: Jul. 10, 2025

(54) METHOD AND APPARATUS WITH WEIGHT ENCODING AND DECODING

(71) Applicants: Samsung Electronics Co., Ltd., Suwon-si (KR); UNIST (Ulsan National Institute of Science and Technology), Ulsan (KR)

(72) Inventors: Hyeonuk SIM, Suwon-si (KR); Hyunchul CHO, Suwon-si (KR); Sugil LEE, Ulsan (KR); Jongeun LEE, Ulsan (KR); Minuk HONG, Ulsan (KR)

(73) Assignees: Samsung Electronics Co., Ltd., Suwon-si (KR); UNIST (Ulsan National Institute of Science and Technology), Ulsan (KR)

(21) Appl. No.: 18/983,671

(22) Filed: Dec. 17, 2024

(30) Foreign Application Priority Data
Jan. 4, 2024 (KR) 10-2024-0001656

(51) Int. Cl. H03M 7/40

(52) U.S. Cl. CPC H03M 7/40

(57) ABSTRACT

Disclosed are an encoder and decoder configured to encode and decode a weight and an operating method of the encoder and the decoder. An operating method of a decoding device includes: receiving a compressed weight including a preceding code and subsequent bits following the preceding code; and decoding the compressed weight by applying the preceding code of the compressed weight to a Huffman tree, wherein the Huffman tree decodes the preceding code, and wherein the decoded preceding code is joined with the subsequent bits to form a decompressed version of the compressed weight.

### CROSS-REFERENCE TO RELATED APPLICATIONS

This application claims the benefit under 35 USC § 119(a) of Korean Patent Application No. 10-2024-0001656, filed on Jan. 4, 2024, in the Korean Intellectual Property Office, the entire disclosure of which is incorporated herein by reference for all purposes.

### BACKGROUND

### 1. Field

The following description relates to an encoder and a decoder for encoding and decoding a weight and an operating method thereof.

### 2. Description of Related Art

Data compression is used in various fields to reduce consumption of data storage space, communication bandwidth, to increase data transfer speed, and the like.

In the field of neural networks, compression techniques are directly related to the learning efficiency and the performance of neural networks. When training a neural network, a reduction in the amount of memory communication and the size of a model weight, as through weight compression, may substantially improve energy efficiency.

Compression techniques may be classified into loss compression and lossless compression, which may also be classified into a fixed length method and a variable length method. Compression in the variable length method, unlike in the fixed length method, may involve delineating pieces of compressed data.

In this regard, run-length encoding is a lossless compression method, which additionally encodes the number of consecutive values and expresses the consecutive numbers as one value and the number.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, an operating method of a decoding device including processing hardware and storage hardware includes: receiving a compressed weight including a preceding code and subsequent bits following the preceding code; and decoding the compressed weight by applying the preceding code of the compressed weight to a Huffman tree, wherein the Huffman tree decodes the preceding code, and wherein the decoded preceding code is joined with the subsequent bits to form a decompressed version of the compressed weight.

The decoding the compressed weight includes: not decoding the subsequent bits that are subsequent to the preceding code while decompressing the compressed weight without converting the value.

The Huffman tree is configured to record a decoding value corresponding to cases of the preceding code.

The preceding code may be determined according to, in the weight before being compressed, the number of consecutive 0s preceding before a first 1 first in the weight before compression.

The decoding the compressed weight may include: filling an insufficient bit of the compressed weight with 1 such that the length of the compressed weight corresponds to a fixed length bit prior to compression.

The receiving the compressed weight may include receiving the compressed weight stored in static random-access memory (SRAM).

The method may further including inputting the decoded weight to an operator for a multiply-accumulate (MAC) operation.

In another general aspect, an operating method of an encoding includes: receiving a weight, the weight having a prefix of bits of all 0s followed by a postfix starting with a bit of a 1; determining the number of bits of 0s in the prefix of the weight; compressing the prefix into a code according to the number of bits of 0s in the prefix; and forming a compressed version of the weight by joining the code with the postfix.

The method may further include generating a Huffman tree configured to record a compressing method based on which zeros-prefix lengths are most common among a set of weights including the weight.

The compressing of the prefix into the code may include: when a first bit is 1, compressing the first bit 1 and connecting a bit value of a subsequent bit to the first bit 1 to the compressed code and displaying the bit value.

The compressing of the prefix into the code may include: converting bits, excluding a first bit from among the bits of 0s, into the code that is predetermined according to the number of bits of 0s.

The determining the number of bits of the preceding 0s may include: providing a counter corresponding to the number of bits of the weight; and determining a bit value of a digit corresponding to the counter while increasing the counter.

A non-transitory computer-readable storage medium may store instructions that, when executed by a processor, cause the processor to perform any of the methods.

In another general aspect, a decoding device including: one or more processors; a memory; and one or more programs stored in the memory that when executed by the one or more processors: receiving a compressed weight including a compression code followed by subsequent uncompressed bits adjoining the preceding code in the compressed weight; and decoding the compressed weight, to a decoded bit string, by hashing the compression code of the compressed weight with reference to a Huffman tree, wherein the Huffman tree includes decoding information of the compression code.

The decoding the compressed weight may include: forming, in a decompressed weight corresponding to the compressed weight, the decompressed bits joined to the uncompressed bits.

The compression code is determined according to the number of 0s preceding before 1 first appears in a weight corresponding to the compressed weight.

The decoding the compressed weight may include: filling an insufficient bit of the compressed weight with 1 such that the length of the compressed weight corresponds to a fixed length bit.

In another general aspect, an encoding device includes: one or more processors; a memory storing instructions configured to cause the one or more processors to: receive a weight; determine the number of bits of consecutive 0s in a prefix of the weight before a first 1 in the weight, the first 1 including the first bit in a postfix of the weight that follows prefix; compress the prefix according to the number of bits of 0s; and form a compressed weight corresponding to the weight by joining the compressed prefix with the postfix.

The compressing of the prefix may include: when a first bit in the prefix is 1, compressing the first bit 1 and connecting a bit value after the first bit 1 to the compressed code and displaying the bit value.

The compressing of the prefix may include: mapping the prefix to a code that is predetermined according to the number of bits of 0s of the prefix.

Other features and aspects will be apparent from the following detailed description, the drawings, and the claims.

### BRIEF DESCRIPTION OF THE DRAWINGS

FIG. 1 illustrates a Huffman coding example.

FIG. 2 illustrates an example compression method, according to one or more embodiments.

FIG. 3 illustrates an example method of compressing a weight in an encoding device, according to one or more embodiments.

FIG. 4 illustrates an example encoding device, according to one or more embodiments.

FIG. 5 illustrates an example of decoding a weight in an operable form in an operator, according to one or more embodiments.

FIG. 6 illustrates an example operating method of a decoding device, according to one or more embodiments.

FIG. 7 illustrates an example decoding device, according to one or more embodiments.

FIG. 8 illustrates an example of a method implemented by a smartphone application processor (AP), according to one or more embodiments.

FIG. 9 illustrates an example of a method implemented by a neural processing unit (NPU), according to one or more embodiments.

Throughout the drawings and the detailed description, unless otherwise described or provided, the same or like drawing reference numerals will be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

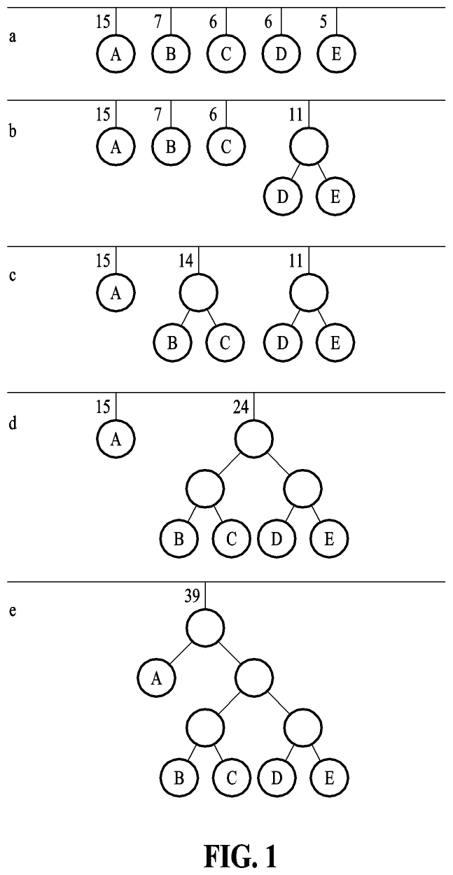

FIG. 1 illustrates a Huffman coding example.

The Huffman coding method is a lossless compression method that uses a statistical distribution of individual values in an a set of data (e.g., a set of weights) to decide how to most efficiently encode the values. The number of bits required to express the entire set of data may be reduced by mapping characters/values with high frequency into codes of relatively few bits and mapping characters/values with relatively low frequency into codes with relatively more bits.

Through the Huffman coding method, data may be compressed while a Huffman tree is formed as illustrated in FIG. 1.

After receiving data to be compressed, an encoder (i) separates bit strings included in the data into units of characters, (ii) sorts the characters in descending order of their cardinalities (highest cardinality first), as shown by line “a” in FIG. 1, (iii) puts two characters with low cardinality together to form a binary tree (D and E in FIG. 1), and records the sum of the cardinalities of the two combined characters. The Huffman tree may be formed by repeating the operation of forming a binary tree with low-cardinality characters among the remaining characters in the same method and recording the number of characters. The connections of the binary tree may be assigned alternating 0s and 1s, as described elsewhere.

Huffman coding may be performed by assigning, as a code for a given character in the binary tree, the string of 0s and 1s on the connections that form the path from the root of the binary tree to the node of the given character. As a result, a binary bit string into which the input data is compressed/encoded may be output; the binary tree acts as a sort of hash map that maps inputs (bit strings) to outputs (shorter bitstrings, i.e., codes).

Since the codes of a Huffman coding have a variable length, hashing may be performed sequentially on the compressed data (Huffman codes) and the length and complexity increases exponentially depending on the type of character. For example, the number of cases when compressing an 8-bit bit string through Huffman coding is 256, the 8-bit bit string may be encoded with a maximum 256-bit length per bit, and the size and depth of the Huffman tree may increase.

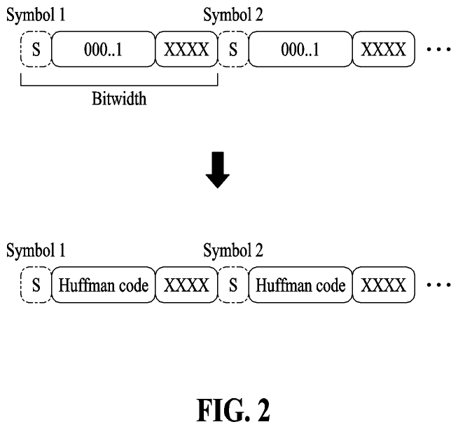

FIG. 2 illustrates an example of a compression method, according to one or more embodiments.

As described above, Huffman coding encodes an array of consecutive bits into individual codes according to statistical distribution of the consecutive bits.

On the other hand, an encoding device may compress a value, for example a weight of a neural network, by counting the number of consecutive 0s in the prefix of the received weight/value and determining a compression code to be used according to the length/number of the consecutive 0s in the prefix.

The encoding device may count the number of 0s before data having a 1 value in the received weight. The weight may be compressed by treating the weight as two parts; the prefix of consecutive 0s bits is compressed (replaced with a corresponding code) and is concatenated with the values of bits in the weight that are subsequent to the first ‘1’.

For example, when an 8-bit weight is compressed in the method described above, a leading/Huffman tree may be generated in 9 cases, including the cases of all bits being ‘0’ and all bits being ‘1’. The generated leading tree (e.g., a Huffman tree) may be used for encoding in an encoding device and for decoding in a decoding device.

In an example of a fixed-point format, a sign bit value of a negative number is expressed by ‘1’, and thus, a first bit value is represented by ‘1’. A compression method of counting the number of preceding 1s may have an effect equivalent to the encoding method described above.

Hereinafter, the compression method of counting the number of consecutive preceding (prefix) 0s is described.

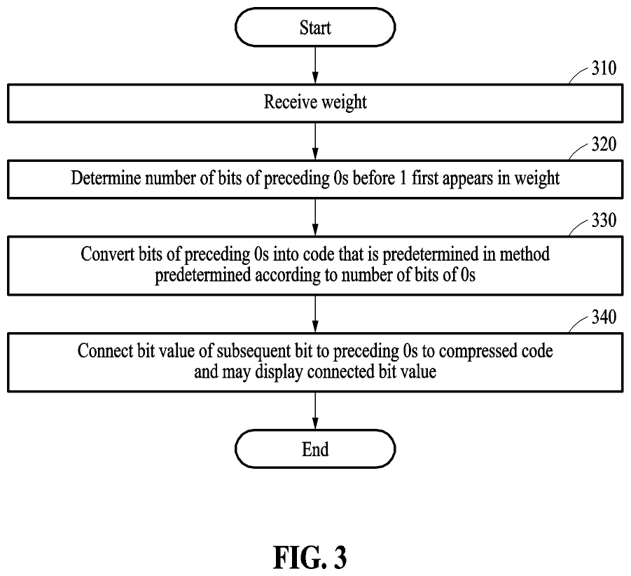

FIG. 3 illustrates an example method of compressing a weight in an encoding device, according to one or more embodiments.

Operations to be described hereinafter may be performed sequentially but not necessarily. For example, the order of the operations may change and at least two of the operations may be performed in parallel.

The encoding device may compress a weight of a neural network through operations 310 to 340. The encoding device, through such compression, may be used to increase communication efficiency and the operation speed of the neural network when relaying weights of the neural network, whether through memory, through a network, etc.

In operation 310, the encoding device may receive a weight to be compressed. The weight may have a data width of a length W. It may be assumed that a Huffman tree has already been generated for the set of weights to which the weight belongs, and thus the Huffman tree reflects the statistical traits of the set of weights.

In operation 320, the encoding device may determine the number of consecutive 0-bits before the first 1-bit in the weight, i.e., may determine the size of the zeros-prefix of the weight.

To do so, the encoding device may have a loop with a current bit starting at the first bit of the weight. For each iteration of the loop, the encoding device checks the value of the current bit. If the value is 1 then the loop exits and knows the count/position of the first 1-bit in the weight. Otherwise, the current bit is incremented by one to the next bit of the weight and the current bit is again checked for a value of 1. For example, when an 8-bit weight is ‘001xxxxx’, the number of bits of preceding 0s (the zeros-prefix) is determined to be 2 bits.

In operation 330, for the weight being compressed/encoded, the encoding device may convert the prefix string of 0-bits (the zeros-prefix) of the weight into a code that is predetermined in a method predetermined according to the numbers of the zeros-prefixes of various sizes (the Huffman tree mentioned earlier). For example, the encoding device may maintain W+1 counters (e.g., 8 bits each), and each counter represents a different zero-prefix length. Thus, by processing all of the weights their zero-prefixes of different lengths can be counted according to their lengths. From this, the Huffman coding tree can be formed as in FIG. 2. Each Huffman code traced through the tree represents a unique length of zeros-prefix and a corresponding code for that zeros-prefix.

For a given weight, the encoding device may count the number of initial consecutive 0-bits and, according to the accumulation/count of zeros-prefixes of that length, may convert the 0-bits of the weight into a certain Hufman binary code according to the number of counted 0-bits.

To reiterate, the encoding device may use a prestored algorithm for this (partly involving Huffman coding). The bits of a given weight with a given zeros-prefix length may be converted into a different binary code according to the number of cases of the zeros-prefix of that length among the set of weights used to build the Huffman tree. In this case, the bits string (excluding 0 that appears first) and up to a bit in which a first 1 appears, may be converted into binary code.

In operation 340, the encoding device may connect/concatenate the compression code of the weight to the part of the weight that follows its zeros-prefix (the uncompressed part) and may treat the connected/concatenated bit string as a compressed version of the weight.

As just noted, subsequent bits to a bit in which a bit value of 1 appears in the converted binary code may be connected after the corresponding binary code and used without being converted. For example, for a weight having a value of ‘00001xxx’, a binary code corresponding to ‘00001’ (e.g., a corresponding Huffman code) may be displayed in a position of 1 and a value of xxx may be connected directly after the binary code as a subsequent bit and used as the compressed weight.

The encoding device may provide a compression method of having a variable length depending on a weight. The number of cases of possible encoding may be generated as a leading/Huffman tree such that the leading/Huffman tree may be referred to for decoding.

As noted earlier, when analyzing multiple weights received by the encoding device, a distribution of the weights (more specifically, the length of their zeros-prefixes) may be identified. By using the distribution of the weights, compression may be performed on weights corresponding to the same distribution in the same method such that compression efficiency may increase.

An encoded weight may be stored in a memory and may be provided to a decoding device for decoding.

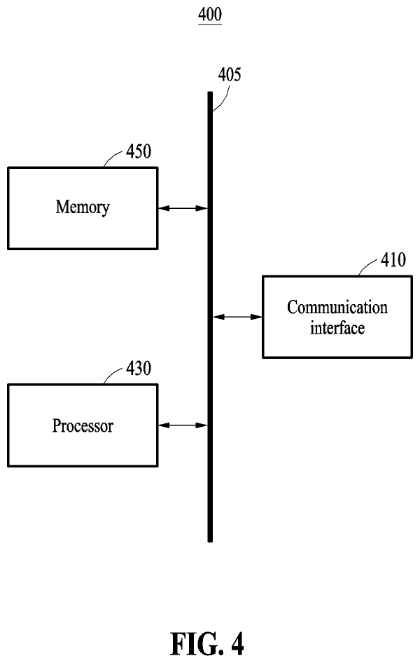

FIG. 4 illustrates an example of an encoding device, according to one or more embodiments.

Referring to FIG. 4, an encoding device 400 according to an embodiment may include a communication interface 410, a processor 430, and a memory 450. The communication interface 410, the processor 430 and the memory 450 may communicate with one another via a communication bus 405.

The communication interface 410 receives weights, e.g., of a neural network model, a kernel/filter, or the like.

The processor 430 may compress the weights received through the communication interface 410 in a predetermined method. The processor 430 may compress a weight by determining a compression code for the weight according to the length (number of bits) of the weight's zeros-prefix that precedes a remaining bit string of the weight, and connecting the compression code with the bits subsequent to the zeros-prefix.

The memory 450 may store various pieces of information generated in the process, described above, performed by the processor 430. In addition, the memory 450 may store various pieces of data, programs, or the like. The memory 450 may include, for example, a volatile memory or a non-volatile memory. The memory 450 may include a massive storage medium, such as a hard disk, and may store the various pieces of data.

In addition, the processor 430 may perform at least one method described with reference to FIGS. 2 and 3 or an algorithm corresponding to the at least one method. The processor 430 may be a hardware-implemented data processing device including a circuit that is physically structured to execute desired operations. For example, the desired operations may include code or instructions in a program. The processor 430 may be implemented as, for example, any of, or any combination of, a central processing unit (CPU), a graphics processing unit (GPU), or a neural processing unit (NPU). The hardware-implemented encoding device 400 may include, for example, a microprocessor, a CPU, a processor core, a multi-core processor, a multiprocessor, an application-specific integrated circuit (ASIC), and a field-programmable gate array (FPGA).

The processor 430 may execute a program and may control the encoding device 400. The code of the program executed by the processor 430 may be stored in the memory 450.

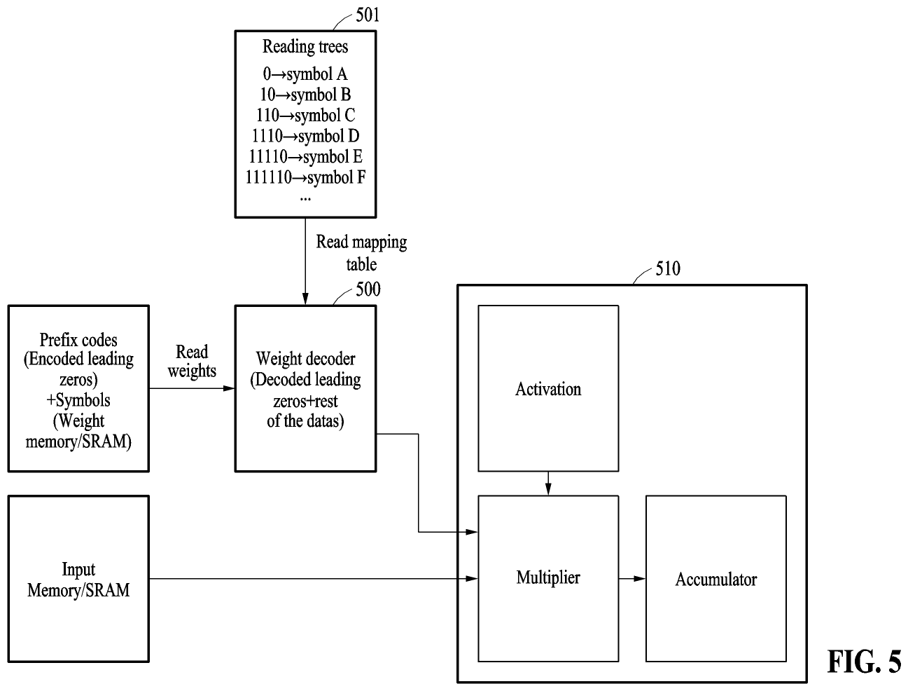

FIG. 5 illustrates an example of decoding a weight in an encoded form, according to one or more embodiments.

A decoding device 500 may decode a weight compressed in the method of FIGS. 2 to 4 such that the weight is operable in an operator 510 (i.e., the decoded weight can be used in any way that the weight is intended to be used).

The decoding device 500 may decode a compressed weight having a variable length due to having been compressed/encoded with reference to a leading/Huffman tree 501.

The leading/Huffman tree 501 may be stored in a memory or may be retrieved from another device. The leading tree 501 may include hash information of a compressed weight. For example, the leading tree 501 may indicate a binary code compressed according to the number of preceding 0s of the weight upon compression.

The decoding device 500 may first convert the length of the received compressed weight into a decompressed weight (to be filled) with a bit number of a fixed length. Since the compressed weight has a variable length, a bit string value (a decoding of the Huffman code part of the compressed weight) may be added to the part of the decompressed weight that corresponds to the fixed length before compression. In other words, the part of the compressed weight that is the compression code may be replaced with the bit string corresponding to, in the leading tree 500, the compression code.

According to the leading tree 501, when the preceding code of the compressed weight is 0, that code may be converted into (replaced with) a symbol A, and, when the preceding code of the compressed weight is 1110, that code may be decoded into a symbol D. Symbols A through F may correspond to zeros-prefixes according to counts/frequencies of the zeros-prefixes.

The compressed weight may be received through a memory, such as static random-access memory (SRAM), configured to store the compressed weight. The compressed weight may be retrieved by reading the memory, the decoding device 500 may obtain a part corresponding to the preceding code (the compression/Huffman code) by hashing the leading tree 501, and the bits to the preceding/compression code may be connected to and displayed after the decompressed bits.

Then, the compressed weight, now decompressed, may have an operable form and may be input to the operator 510. The operator 510 may perform a multiply-accumulate (MAC) operation, for example, on an input by using the original/decompressed weight obtained by the decoding device 500.

In this case, the memory that stores the input weight may be reused for operations. By reducing the size of the consumed memory, the size and power consumption of memory may be reduced.

In the operator 510, a MAC operation may be performed on a weight and an input (activation), which is performed before/without compression, and an output obtained through the operator 510 may be an input of a next layer or a final output value.

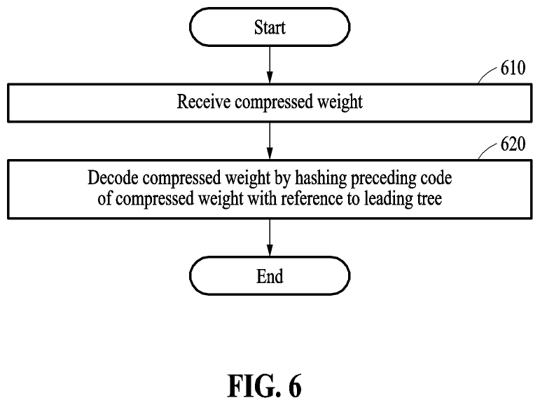

FIG. 6 illustrates an example of an operating method of a decoding device, according to one or more embodiments.

In operation 610, the decoding device may receive a compressed weight.

The compressed weight may include a preceding code (a compressed portion) and subsequent bits connected to the preceding code. The preceding code may correspond to compressed bits.

The decoding device may receive the compressed weight and may convert the length/portion of the compressed weight into a length corresponding to a fixed length. For example, when the length of the compressed weight for a weight having an 8-bit fixed length is 5 bits, a missing 3-bit bit value 111 may be added to the compressed weight such that the length of the compressed weight may become 8 bits. The bit value may be added prior to the preceding code.

In operation 620, the decoding device may decode the compressed weight by hashing the preceding code of the compressed weight with reference to a leading tree (i.e., decoding the Huffman code to the bitstring it represents).

The leading tree may be stored in a memory or may be retrieved from a memory. The leading tree may include hash information of the leading tree. The leading tree may indicate information on a binary code compressed according to the number of preceding/prefix 0s of a weight before compression. For example, the leading tree may be referred to, including a bit string of 1s added to correspond to a fixed length bit, such that the compression information of each bit string before compression may be distinguished. The example of the leading tree is provided with reference to FIG. 5.

The decoding device may hash a part of the weight corresponding to the preceding code from the leading tree and display/combine the part and may connect and display a subsequent bit (the uncompressed part of the weight) to the preceding code after the hashed code without hashing.

In other words, a decoded weight may be expressed by a form of the hash information of preceding code+a subsequent bit, which together may correspond to a fixed length.

The decoded weight may be used for a MAC operation, for example.

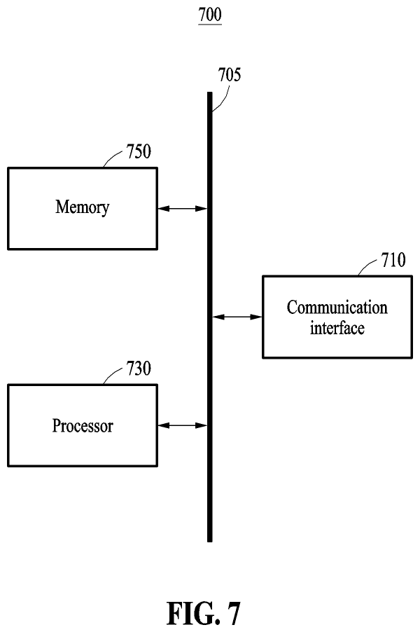

FIG. 7 illustrates an example of a decoding device according to one or more embodiments.

Referring to FIG. 7, a decoding device 700 according to an embodiment may include a communication interface 710, a processor 730, and a memory 750. The communication interface 710, the processor 730, and the memory 750 may communicate with one another via a communication bus 705.

The communication interface 710 may receive compressed weights.

The processor 730 may decode the compressed weights in a predetermined method through the communication interface 710. The processor 730 may decode a compressed weight by converting a preceding code by using a bit string corresponding to the preceding code of the weight and connecting a subsequent bit thereto and displaying/forming it.

The memory 750 may store various pieces of information generated in the process, described above, performed by the processor 730. In addition, the memory 750 may store various types of data and programs. The memory 750 may include a volatile memory or a non-volatile memory. The memory 750 may include a massive storage medium, such as a hard disk, and may store the various pieces of data.

In addition, the processor 730 may perform the at least one method described above or an algorithm corresponding to the at least one method. The processor 730 may be a hardware-implemented data processing device including a circuit that is physically structured to execute desired operations. For example, the desired operations may include code or instructions in a program. The processor 430 may be implemented as, for example, a CPU, a GPU, or an NPU. The hardware-implemented decoding device 700 may include, for example, a microprocessor, a CPU, a processor core, a multi-core processor, a multiprocessor, an ASIC, and an FPGA.

The processor 730 may execute a program and may control the decoding device 700. The code of the program executed by the processor 730 may be stored in the memory 750.

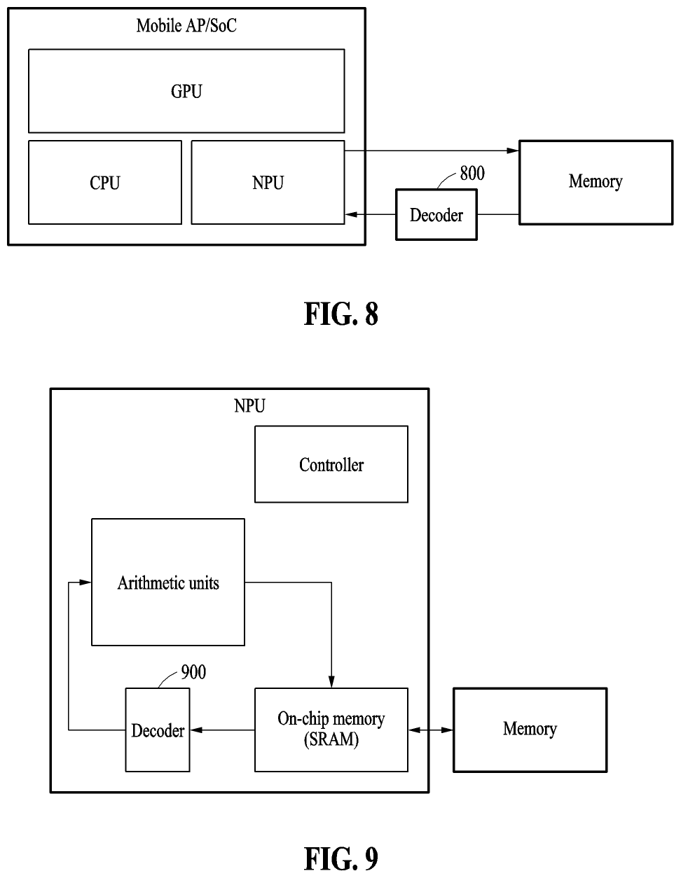

FIG. 8 illustrates an example of a method implemented by a smartphone application processor (AP), according to tone or more embodiments.

FIG. 8 schematically shows the internal configuration of the smartphone AP. An embodiment of encoding performed in the same location as that of the AP and a decoder 800 built in the AP is illustrated.

The smartphone AP may include an NPU. The NPU may be equipped for operations, such as MAC. The NPU may receive a weight obtained through decoding in the decoding device 800 and may perform a MAC operation on a decoded input.

When a smartphone's NPU operates a neural network, a large volume of power is consumed to read a weight from an external memory. When receiving a compressed weight in the encoding method described above, a consumed communication amount and power may be reduced.

If the neural network processing speed decreases when reading a weight, the neural network processing speed may be increased by reducing a communication amount for this.

FIG. 9 illustrates an example of a method implemented by an NPU, according to one or more embodiments.

The NPU of FIG. 9 is used to reduce power consumption. An internal memory (e.g., an on-chip memory or SRAM) receives compressed weights, and a decoder 900 may be implemented by being connected to the internal memory such that the compressed weights may be decoded when using an operator.

The costs of the internal memory and the power consumed to read data may be additionally saved. On the other hand, since the number of reads in the internal memory is greater than the number of reads in an external memory, the power consumed for decoding may increase.

The computing apparatuses, the electronic devices, the processors, the memories, the displays, the information output system and hardware, the storage devices, and other apparatuses, devices, units, modules, and components described herein with respect to FIGS. 1-9 are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-9 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. An operating method of a decoding device comprising processing hardware and storage hardware, the operating method comprising:
receiving a compressed weight comprising a preceding code and subsequent bits following the preceding code; and
decoding the compressed weight by applying the preceding code of the compressed weight to a Huffman tree, wherein
the Huffman tree decodes the preceding code, and wherein the decoded preceding code is joined with the subsequent bits to form a decompressed version of the compressed weight.

2. The operating method of claim 1, wherein the decoding the compressed weight comprises:
not decoding the subsequent bits that are subsequent to the preceding code while decompressing the compressed weight without converting the value.

3. The operating method of claim 1, wherein the Huffman tree is configured to record a decoding value corresponding to cases of the preceding code.

4. The operating method of claim 1, wherein the preceding code is determined according to, in the weight before being compressed, the number of consecutive 0s preceding before a first 1 first in the weight before compression.

5. The operating method of claim 1, wherein the decoding the compressed weight comprises:
filling an insufficient bit of the compressed weight with 1 such that the length of the compressed weight corresponds to a fixed length bit prior to compression.

6. The operating method of claim 1, wherein the receiving the compressed weight comprises receiving the compressed weight stored in static random-access memory (SRAM).

7. The operating method of claim 1, further comprising inputting the decoded weight to an operator for a multiply-accumulate (MAC) operation.

8. An operating method of an encoding device, the operating method comprising:
receiving a weight, the weight having a prefix of bits of all 0s followed by a postfix starting with a bit of a 1;
determining the number of bits of 0s in the prefix of the weight;
compressing the prefix into a code that is predetermined according to the number of bits of 0s in the prefix; and
forming a compressed version of the weight by joining the code with the postfix.

9. The operating method of claim 8, further comprising generating a Huffman tree configured to record a compressing method based on which zeros-prefix lengths are most common among a set of weights including the weight.

10. The operating method of claim 8, wherein the compressing of the prefix into the code comprises:
when a first bit is 1, compressing the first bit 1 and connecting a bit value of a subsequent bit to the first bit 1 to the compressed code and displaying the bit value.

11. The operating method of claim 8, wherein the compressing of the prefix into the code comprises:
converting bits, excluding a first bit from among the bits of 0s, into the code that is predetermined according to the number of bits of 0s.

12. The operating method of claim 8, wherein the determining the number of bits of the preceding 0s comprises:
providing a counter corresponding to the number of bits of the weight; and
determining a bit value of a digit corresponding to the counter while increasing the counter.

13. A non-transitory computer-readable storage medium storing instructions that, when executed by a processor, cause the processor to perform the method of claim 8.

14. A decoding device comprising:
one or more processors;
a memory; and
one or more programs stored in the memory that when executed by the one or more processors:
receiving a compressed weight comprising a compression code followed by subsequent uncompressed bits adjoining the preceding code in the compressed weight; and
decoding the compressed weight, to a decoded bit string, by hashing the compression code of the compressed weight with reference to a Huffman tree, wherein
the Huffman tree comprises decoding information of the compression code.

15. The decoding device of claim 14, wherein the decoding the compressed weight comprises:
forming, in a decompressed weight corresponding to the compressed weight, the decompressed bits joined to the uncompressed bits.

16. The decoding device of claim 14, wherein the compression code is determined according to the number of 0s preceding before 1 first appears in a weight corresponding to the compressed weight.

17. The decoding device of claim 14, wherein the decoding the compressed weight comprises:
filling an insufficient bit of the compressed weight with 1 such that the length of the compressed weight corresponds to a fixed length bit.

18. An encoding device comprising:
one or more processors;
a memory storing instructions configured to cause the one or more processors to:
receive a weight;
determine the number of bits of consecutive 0s in a prefix of the weight before a first 1 in the weight, the first 1 comprising the first bit in a postfix of the weight that follows prefix;
compress the prefix according to the number of bits of 0s; and
form a compressed weight corresponding to the weight by joining the compressed prefix with the postfix.

19. The encoding device of claim 18, wherein the compressing of the prefix comprises:
when a first bit in the prefix is 1, compressing the first bit 1 and connecting a bit value after the first bit 1 to the compressed code and displaying the bit value.

20. The encoding device of claim 18, wherein the compressing of the prefix comprises:
mapping the prefix to a code that is predetermined according to the number of bits of 0s of the prefix.
